(19) United States
(12) Patent Application Publication
(10) Pub. No.: US 2024/0321662 A1
(43) Pub. Date: Sep. 26, 2024

(54) ELECTRONIC COMPONENT AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Yutaka ONOZUKA, Yokohama Kanagawa (JP); Tomohiro SAITO, Yokohama Kanagawa (JP); Kazuyuki HIGASHI, Yokohama Kanagawa (JP); Kazumichi TSUMURA, Shinagawa Tokyo (JP)

(21) Appl. No.: 18/453,682

(22) Filed: Aug. 22, 2023

(30) Foreign Application Priority Data
Mar. 22, 2023 (JP) 2023-046063

(51) Int. Cl. H01L 23/31; H01L 23/00; H01L 23/13; H01L 23/498; H05K 1/18

(52) U.S. Cl. CPC H01L 23/3121; H01L 23/13; H01L 23/49811; H01L 24/13; H01L 24/14; H01L 24/16; H05K 1/181; H01L 24/32; H01L 24/48; H01L 24/73; H01L 2224/13013; H01L 2224/1416; H01L 2224/16225; H01L 2224/32225; H01L 2224/48091; H01L 2224/48105; H01L 2224/48227; H01L 2224/73265; H05K 2201/10734

(57) ABSTRACT

An electronic component includes: a first substrate having a first surface with a first region and a second region, a plurality of first bumps provided in the first region, and zero or one or more second bumps provided in the second region, the number of second bumps being smaller than the number of first bumps; and a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance, the number of fourth bumps being smaller than the number of third bumps.

### CROSS-REFERENCE TO RELATED APPLICATION

This application is based upon and claims the benefit of priority from Japanese Patent Application No. 2023-046063, filed on Mar. 22, 2023, the entire contents of which are incorporated herein by reference.

### FIELD

Embodiments described herein relate generally to an electronic component and a method for manufacturing the same.

### BACKGROUND

An electronic component is known in which a semiconductor package, in which a semiconductor chip is mounted, is electrically connected to a printed wiring board.

In addition, an electronic component is known in which pixels formed on a semiconductor substrate are connected to each other by using a variable resistance circuit formed by a metal oxide semiconductor field effect transistor (MOSFET) and smoothing processing between the pixels is performed at high speed.

### BRIEF DESCRIPTION OF THE DRAWINGS

FIG. 1 is a schematic cross-sectional view of an electronic component according to a first embodiment;

FIG. 2 is a schematic perspective view of a main part of the electronic component according to the first embodiment;

FIG. 3 is a schematic diagram of an electronic component according to a second embodiment;

FIG. 4 is a circuit diagram of a main part of the electronic component according to the second embodiment;

FIG. 5 is a circuit diagram of the main part of the electronic component according to the second embodiment;

FIG. 6 is a schematic cross-sectional view of the main part of the electronic component according to the second embodiment; and

FIG. 7 is a schematic perspective view of the main part of the electronic component according to the second embodiment.

### DETAILED DESCRIPTION

An electronic component of embodiments includes: a first substrate having a first surface with a first region and a second region, a plurality of first bumps provided in the first region, and zero or one or more second bumps provided in the second region, the number of second bumps being smaller than the number of first bumps; and a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance, the number of fourth bumps being smaller than the number of third bumps.

Hereinafter, embodiments will be described with reference to the diagrams. In addition, in the diagrams, the same or similar elements are denoted by the same or similar reference numerals.

In this specification, the same or similar members are denoted by the same reference numerals, and the repeated descriptions thereof may be omitted.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

### First Embodiment

An electronic component of embodiments includes: a first substrate having a first surface with a first region and a second region, a plurality of first bumps provided in the first region, and zero or one or more second bumps provided in the second region, the number of second bumps being smaller than the number of first bumps; and a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance, the number of fourth bumps being smaller than the number of third bumps.

A method for manufacturing an electronic component of embodiments includes: bonding a plurality of first bumps of a first substrate and a plurality of third bumps of a second substrate to each other; and bonding a second bump of the first substrate and a fourth bump of the second substrate to each other. The first substrate includes a first surface with a first region and a second region; the first bumps provided in the first region; and zero or one or more second bumps provided in the second region, the number of second bumps being smaller than the number of first bumps. The second substrate includes a second surface with a third region facing the first surface and the first region and a fourth region facing the second region; the third bumps provided in the third region; zero or one or more fourth bumps provided in the fourth region, the number of fourth bumps being smaller than the number of third bumps; a third surface provided on a side opposite to the third region and having a first distance from the second surface; and a fourth surface provided on a side opposite to the fourth region and having a second distance from the second surface shorter than the first distance.

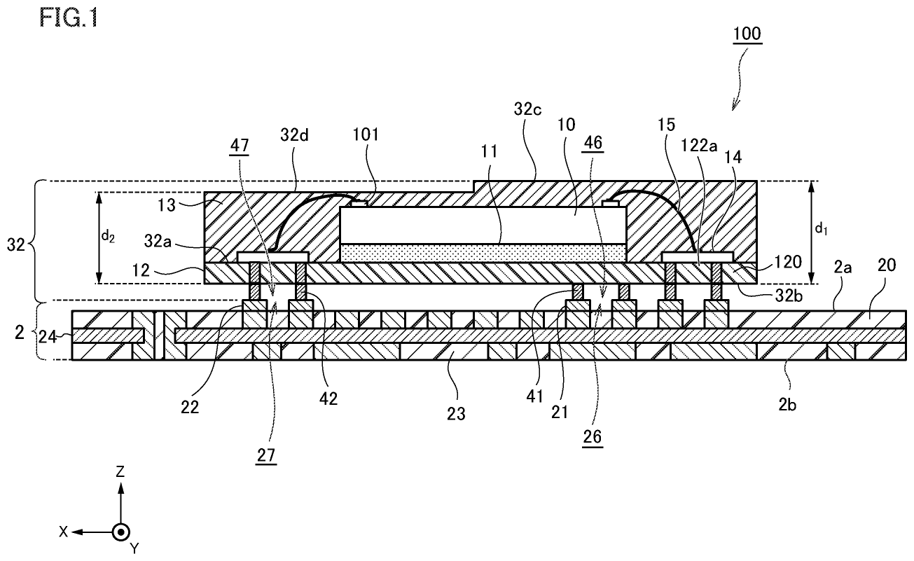

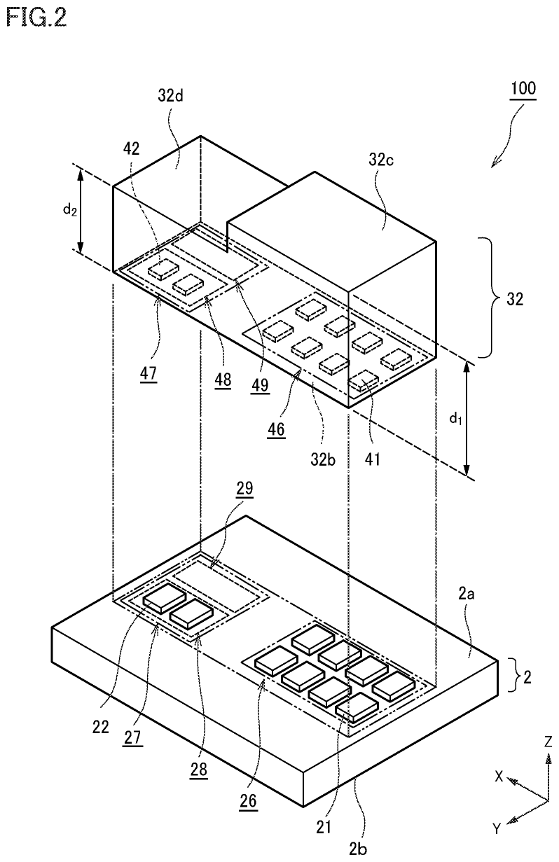

FIG. 1 is a schematic cross-sectional view of an electronic component 100 of embodiments. FIG. 2 is a schematic perspective view showing a main part of the electronic component 100 of embodiments. In addition, in FIG. 2, a plurality of first bumps 21 and a plurality of third bumps 41 are shown separated from each other for easy understanding. In addition, in FIG. 2, a second bump 22 and a fourth bump 42 are shown separated from each other for easy understanding.

The electronic component 100 includes a printed wiring board 2 and a semiconductor package 32.

In addition, the printed wiring board 2 is an example of a first substrate. In addition, the semiconductor package 32 is an example of a second substrate.

The printed wiring board 2 includes a mounting substrate 23, a wiring layer 24, a circuit protection layer 20, the first bump 21, and the second bump 22. In addition, the printed wiring board 2 has a first surface 2a, which is an upper surface of the printed wiring board 2, and a sixth surface 2b, which is a lower surface of the printed wiring board 2.

Here, an X direction, a Y direction perpendicular to the X direction, and a Z direction perpendicular to the X and Y directions are defined. It is assumed that the first surface 2a of the printed wiring board 2, the sixth surface 2b of the printed wiring board 2, and a second surface 32b, a third surface 32c, and a fourth surface 32d of a semiconductor package, which will be described later, are arranged in parallel to the XY plane, for example.

The mounting substrate 23 contains, for example, an insulating material such as glass epoxy resin.

The wiring layer 24 is provided on the mounting substrate 23. The wiring layer 24 contains, for example, a conductive material such as gold (Au), silver (Ag), copper (Cu), aluminum (Al), nickel (Ni), palladium (Pd), and tungsten (W).

The circuit protection layer 20 is provided on the wiring layer 24. The circuit protection layer 20 contains, for example, an insulating material such as solder resist.

The first surface 2a has a first region 26 and a second region 27.

A plurality of first bumps 21 are provided in the first region 26. The plurality of first bumps 21 are electrically connected to the wiring layer 24 through the circuit protection layer 20, for example. The plurality of first bumps 21 are, for example, terminals containing the conductive material described above. In addition, the plurality of first bumps 21 may be solder paste applied or printed in the first region 26. The plurality of first bumps 21 are provided, for example, in an array.

The second bump 22 is provided in the second region 27. The second bump 22 is electrically connected to the wiring layer 24 through the circuit protection layer 20, for example. The second bump 22 is, for example, a terminal containing the conductive material described above. In addition, the second bump 22 may be solder paste applied or printed in the second region 27. The number of second bumps 22 is smaller than the number of first bumps 21. The number of second bumps 22 is zero or one or more.

The number of the plurality of first bumps 21 shown in FIG. 2 is eight. In addition, the number of second bumps 22 shown in FIG. 2 is two. However, the number of first bumps 21 and the number of second bumps 22 are not limited to those shown in FIG. 2.

For example, the second region 27 has a fifth region 28 having one or more second bumps 22 and a sixth region 29 having no second bump 22.

The semiconductor package 32 includes a semiconductor chip 10, a film-like adhesive 11, a wiring substrate 12, a sealing resin 13, a bonding pad 14, a conductive member 15, the third bumps 41, and the fourth bump 42.

The wiring substrate 12 is an insulating resin wiring substrate, a ceramics wiring substrate, or the like having multi-layer wiring (not shown) on its surface or inside. More specifically, the wiring substrate 12 is, for example, a printed wiring substrate using glass epoxy resin. The surface of the wiring substrate 12 is covered with a solder resist (not shown), for example, to protect the wiring. The wiring substrate 12 has the second surface 32b facing the first surface 2a and a fifth surface 32a.

The second surface 32b has a third region 46 facing the first region 26 and a fourth region 47 facing the second region 27.

A plurality of third bumps 41 are provided in the third region 46. The plurality of third bumps 41 are electrically connected to the multi-layer wiring of the wiring substrate 12, for example. The plurality of third bumps 41 are, for example, terminals containing the conductive material described above. In addition, the plurality of third bumps 41 may be solder paste applied or printed in the third region 46. The plurality of third bumps 41 are in contact with the plurality of first bumps 21. The plurality of third bumps 41 are connected to the plurality of first bumps 21. For example, the number of the plurality of third bumps 41 is equal to the number of the plurality of first bumps 21. However, the number of the plurality of third bumps 41 does not have to be equal to the number of the plurality of first bumps 21.

The fourth bump 42 is provided in the fourth region 47. The fourth bump 42 is electrically connected to the multi-layer wiring of the wiring substrate 12. The fourth bump 42 is, for example, a terminal containing the conductive material described above. In addition, the fourth bump 42 may be solder paste applied or printed in the fourth region 47. The number of fourth bumps 42 is smaller than the number of third bumps 41. The fourth bump 42 is in contact with the second bump 22. The fourth bump 42 is connected to the second bump 22. For example, the number of fourth bumps 42 is equal to the number of second bumps 22. However, the number of fourth bumps 42 does not have to be equal to the number of second bumps 22.

The number of the plurality of third bumps 41 shown in FIG. 2 is eight. In addition, the number of fourth bumps 42 shown in FIG. 2 is two. However, the number of third bumps 41 and the number of fourth bumps 42 are not limited to those shown in FIG. 2.

For example, the fourth region 47 has a seventh region 48 having one or more fourth bumps 42 and an eighth region 49 having no fourth bump 42.

The bonding pad 14 is provided on the fifth surface 32a of the wiring substrate 12.

The semiconductor chip 10 is provided on the fifth surface 32a of the wiring substrate 12. The semiconductor chip 10 is, for example, a memory element such as a NAND flash memory or a dynamic random access memory (DRAM). The semiconductor chip 10 is, for example, an arithmetic element such as a microprocessor, or a signal processing element. However, the semiconductor chip 10 is not limited to this.

The semiconductor chip 10 is fixed to the fifth surface 32a by using the film-like adhesive 11, for example. The film-like adhesive 11 is, for example, an adhesive using a thermosetting resin such as epoxy resin, polyimide resin, or acrylic resin. As the film-like adhesive 11, for example, a die attach film (DAF) or a film on wire (FOW) in which a conductive wire can be embedded is used. The semiconductor chip 10 is fixed to the wiring substrate 12 through the film-like adhesive 11.

A pad 101 is provided on the surface of the semiconductor chip 10. The conductive member 15 electrically connects the pad 101 and the bonding pad 14 to each other. The conductive member 15 is, for example, a conductive wire. The periphery of the semiconductor chip 10 is sealed with the sealing resin 13 provided on the fifth surface 32a of the wiring substrate 12.

The sealing resin 13 of the semiconductor package 32 has the third surface 32c and the fourth surface 32d. In other words, the third surface 32c and the fourth surface 32d are the upper surface of the sealing resin 13 of the semiconductor package 32. The third surface 32c is provided on a side opposite to the third region 46. The fourth surface 32d is provided on a side opposite to the fourth region 47.

The distance between the third surface 32c and the second surface 32b is a first distance d1. The distance between the fourth surface 32d and the second surface 32b is a second distance d2 shorter than the first distance d1.

It is preferable that the second distance d2 is 90% or more of the first distance d1.

It is preferable that the third area of the third bump 41 within a plane parallel to the second surface 32b is smaller than the first area of the plurality of first bumps 21 within a plane parallel to the first surface 2a.

It is preferable that the fourth area of the fourth bump 42 within a plane parallel to the second surface 32b is smaller than the second area of the second bump 22 within a plane parallel to the first surface 2a.

Next, a method for manufacturing the electronic component 100 of embodiments will be described.

A method for manufacturing an electronic component of embodiments includes: bonding a plurality of first bumps of a first substrate and a plurality of third bumps of a second substrate to each other; and bonding a second bump of the first substrate and a fourth bump of the second substrate to each other. The first substrate includes a first surface with a first region and a second region; the first bumps provided in the first region; and zero or one or more second bumps provided in the second region, the number of second bumps being smaller than the number of first bumps. The second substrate includes a second surface with a third region facing the first surface and the first region and a fourth region facing the second region; the third bumps provided in the third region; zero or one or more fourth bumps provided in the fourth region, the number of fourth bumps being smaller than the number of third bumps; a third surface provided on a side opposite to the third region and having a first distance from the second surface; and a fourth surface provided on a side opposite to the fourth region and having a second distance from the second surface shorter than the first distance.

The above bonding is performed, for example, by pressure-bonding the plurality of first bumps 21 and the plurality of third bumps 41 to each other and pressure-bonding the second bump 22 and the fourth bump 42 to each other and then heating the printed wiring board 2 and the semiconductor package 32. In such pressure bonding, for example, the third surface 32c and the fourth surface 32d are pressed against the sixth surface 2b by using a known press machine or the like.

Next, the function and effect of the electronic component of embodiments will be described.

When pressure bonding is used for manufacturing as in the case of the electronic component of embodiments, a problem of bump bonding failure may occur if pressure distribution is not uniform. Specifically, for example, when bonding a plurality of first bumps 21 arranged in an array to a plurality of third bumps 41 arranged in an array, there is a problem that the Z-direction lengths of the first bumps 21 and the third bumps 41 bonded to each other are particularly short near the edge of the array compared with the central portion of the array. In other words, for example, when bonding a plurality of first bumps 21 arranged in an array to a plurality of third bumps 41 arranged in an array, there is a problem that the Z-direction heights of the first bumps 21 and the third bumps 41 bonded to each other are particularly low near the edges of the array compared with the central portion of the array.

The above problem is considered to be caused by pressure concentration during bonding. That is, the density of bumps is relatively low near the edges of the array compared with the central portion of the array where many bumps are arranged periodically. Therefore, it is believed that pressure concentrates on the bumps near the edges of the array. In addition, when an isolated bump is provided by providing a test element group (TEG) or the like, it is considered that pressure concentrates on the isolated bump.

In addition, a case can be considered in which after bonding is completed, bumps peel off due to the restoring force that causes the substrate, on which the bumps are provided, to return to its original shape when the pressure is released and accordingly, a bonding failure occurs. For this reason, it is preferable to avoid pressure concentration during bonding as much as possible.

Therefore, the electronic component 100 of embodiments includes: a first substrate having a first surface with a first region and a second region, a plurality of first bumps provided in the first region, and zero or one or more second bumps provided in the second region, the number of second bumps being smaller than the number of first bumps; and a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance.

In the electronic component 100, the second bump 22 and the fourth bump 42 are bonded to each other through the fourth surface 32d, which is closer to the second surface 32b than the third surface 32c. Therefore, pressure concentration applied to the first bump 21 near the edge of the array and the third bump 41 near the edge of the array can be reduced. In addition, even when the second bump 22 and the fourth bump 42 are provided, pressure concentration applied to the second bump 22 and the fourth bump 42 can be reduced. Therefore, stress concentration during bonding is suppressed. As a result, it is possible to provide the electronic component 100 having a more uniform length in the Z direction (height in the Z direction).

It is preferable that the third area of the third bump 41 within a plane parallel to the second surface 32b is smaller than the first area of the plurality of first bumps 21 within a plane parallel to the first surface 2a. In addition, it is preferable that the fourth area of the fourth bump 42 within a plane parallel to the second surface 32b is smaller than the second area of the second bump 22 within a plane parallel to the first surface 2a. This is to prevent the third bump 41 from protruding from the top of the first bump 21 even if the position of the third bump 41 deviates from the position of the first bump 21 when pressure bonding is performed. In addition, this is to prevent the fourth bump 42 from protruding from the top of the second bump 22 even if the position of the fourth bump 42 deviates from the position of the first bump 21 when pressure bonding is performed.

It is preferable that the second distance d2 is 90% or more of the first distance d1. This is because if the second distance d2 is less than 90% of the first distance d1, the second distance d2 is too short and accordingly, pressure bonding between the second bump 22 and the fourth bump 42 becomes difficult.

According to the electronic component of embodiments, it is possible to provide an electronic component in which stress concentration during bonding is suppressed.

### Second Embodiment

An electronic component 200 of embodiments includes an imaging element.

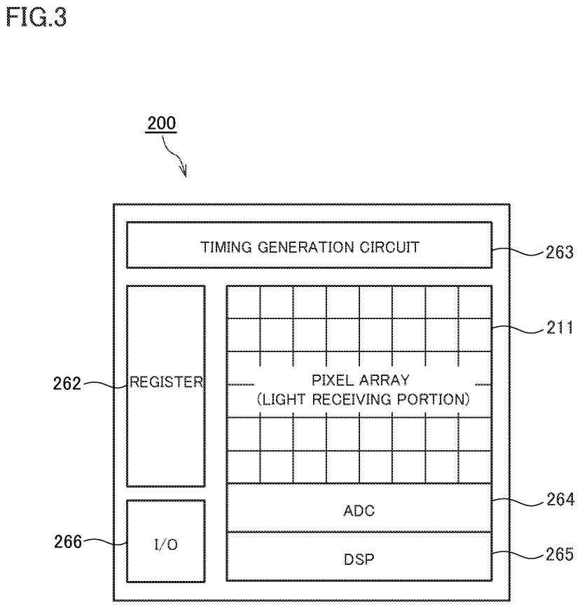

FIG. 3 is a diagram showing the schematic configuration of the electronic component 200 of embodiments.

The electronic component 200 includes a pixel array 211 as an imaging element, a register 262, a timing generation circuit 263, an analog-to-digital converter (ADC) 264, a digital signal processor (DSP) 265, and an input/output (I/O) 266.

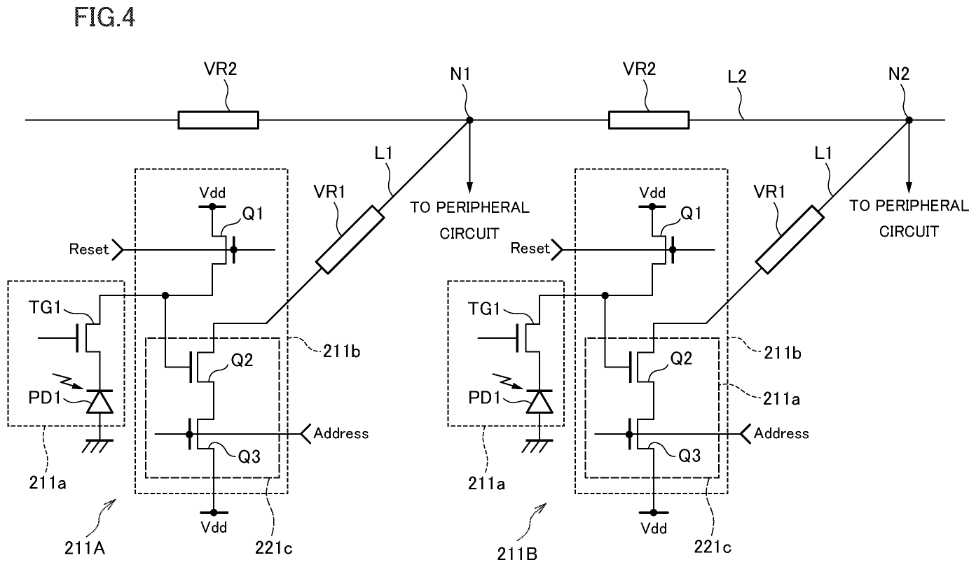

The pixel array 211 is an imaging element in which a plurality of pixels (hereinafter, referred to as pixel cells) each including a light receiving element are arranged in a two-dimensional manner. FIG. 4 is a circuit diagram showing a schematic configuration example of an imaging element of embodiments. In addition, FIG. 4 illustrates a configuration in which two pixel cells 211A and 211B are connected to one first wiring L2. However, the pixel array 211 in FIG. 3 may have a configuration in which a plurality of pixel cells are connected to each of a plurality of wirings.

The pixel cell 211A includes a light receiving portion 211a and a scanning circuit 211b. The light receiving portion 211a includes a photodiode PD1 and a transfer gate TG1. The scanning circuit 211b includes a reset transistor Q1 and an amplifier circuit 211c. The amplifier circuit 211c is a source follower circuit formed by two MOSFETs (hereinafter, referred to as MOS transistors) Q2 and Q3 whose sources are connected to each other. Of the two MOS transistors Q2 and Q3, the MOS transistor Q2 is an amplifier transistor that amplifies the potential corresponding to the charges stored in the light receiving portion 211a with a predetermined gain. In addition, the MOS transistor Q3 is a switching transistor for selecting a pixel cell that is a read target. Hereinafter, the MOS transistor Q2 will be referred to as an amplifier transistor Q2, and the MOS transistor Q3 will be referred to as a switching transistor Q3. In addition, the MOS transistor Q3 may be connected to the source side of the MOS transistor Q2, which is an amplifier transistor, or may be removed from a pixel portion including the light receiving portion 211a and the scanning circuit 211b.

The cathode of the photodiode PD1 in the light receiving portion 211a is connected to the gate of the amplifier transistor Q2 in the amplifier circuit 211c of the scanning circuit 211b through the transfer gate TG1. The photodiode PD1 receives incident light and converts the incident light into electrons. The transfer gate TG1 transfers the electrons generated in the photodiode PD1 to a charge storage region called a floating diffusion (FD). As a result, charges corresponding to the intensity of the incident light are stored in the charge storage region.

A power supply line Vdd is connected to the gate of the amplifier transistor Q2 through the reset transistor Q1. A reset signal Reset for resetting the charge stored in the charge storage region is applied to the gate of the reset transistor Q1. That is, the reset transistor Q1 has a role of resetting the potential of the charge storage region before reading a signal from the light receiving portion 211a (pixel).

In addition, an address signal Address for controlling the charge read from the light receiving portion 211a is input to the gate of the switching transistor Q3 in the amplifier circuit 211c. The source of the amplifier transistor Q2 in the amplifier circuit 211c is connected to a node N1 of the first wiring L2 through a second wiring L1 on which a variable resistance element VR1 is provided. Therefore, a gate potential corresponding to the charges stored in the charge storage region through transfer gate TG1 is generated at the gate of the amplifier transistor Q2. Since the amplifier circuit 211c is a source follower circuit, the gate potential generated at the gate of the amplifier transistor Q2 is converted into the source potential of the amplifier transistor Q2. As a result, the source potential of the amplifier transistor Q2 becomes a potential corresponding to the amount of light received by the photodiode PD1. This source potential is applied to the node N1 through the variable resistance element VR1 on the second wiring L1.

The configuration of the pixel cell 211A described above is the same for the pixel cell 211B and other pixel cells (not shown). Therefore, for example, in the case of the pixel cell 211B, when the address signal Address is applied to the gate of the switching transistor Q3 while a selection signal is being applied to the transfer gate TG1, the gate potential of the amplifier transistor Q2 corresponding to the charge stored in the charge storage region is converted into the source potential to be applied to a node N2 through the variable resistance element VR1 on the second wiring L1.

In addition, a variable resistance element VR2 is provided on the first wiring L2 between adjacent pixel cells (for example, the pixel cells 211A and 211B) among the plurality of pixel cells connected to the same first wiring L2. For example, the variable resistance element VR2 is provided between the nodes N1 and N2 where the pixel cells 211A and 211B adjacent to each other are connected to the first wiring L2. Therefore, a voltage value (light amount value) output from each of the nodes N1 and N2 to the peripheral circuit is a value smoothed according to a ratio R1/R2 between the resistance value R1 of the variable resistance element VR1 provided on each second wiring L1 and the resistance value R2 of the variable resistance element VR2 on the first wiring L2. In addition, smoothing is to reduce the difference in brightness value between adjacent pixels to smooth edges in an image.

If the ratio R1/R2 is large, the degree of smoothness is large, and if the ratio R1/R2 is small, the degree of smoothness is small. For example, if the resistance value R2 is set to be very larger than the resistance value R1, the voltage value (light amount value) output from each of the nodes N1 and N2 is hardly smoothed. As a result, substantially raw image data is read out from the pixel array 211. On the other hand, if the resistance value R2 is set to be smaller than the resistance value R1, the voltage value (light amount value) output from each of the nodes N1 and N2 is smoothed relatively strongly. As a result, greatly smoothed image data is read out from the pixel array 211. By changing the ratio R1/R2 in this manner, it is possible to generate image data with different degrees of smoothness. Therefore, it is possible to perform analog smoothing of pixels and creation of a Gaussian pyramid formed by a plurality of pieces of image information with different degrees of smoothness while suppressing an increase in pixel area in the pixel array 211 as much as possible. In addition, by performing difference processing, feature point extraction, and feature amount extraction on images with different degrees of smoothness in the peripheral circuit portion, it is possible to perform basic processing required for image recognition processing at high speed. For example, by performing difference processing on two pieces of image data read out from the pixel array 211 as image data with different degrees of smoothness, it is possible to generate a so-called edge image at high speed by extracting the edges in the image. In addition, difference processing, feature point extraction processing, and feature amount extraction processing on images with different degrees of smoothness may be performed by application software executed in an information processing device, such as a central processing unit (CPU), without being limited to the peripheral circuit.

In addition, although the pixel cells adjacent to each other in the one-dimensional direction are connected to each other through the variable resistance element VR2 in FIG. 4, pixel cells vertically and horizontally adjacent to each other may be connected to each other through the variable resistance element VR2. When the variable resistance element VR2 is interposed between the pixel cells adjacent to each other in the one-dimensional direction, one-dimensionally smoothed image data can be extracted from the pixel array 211. On the other hand, when the variable resistance element VR2 is interposed between the pixel cells vertically and horizontally adjacent to each other, two-dimensionally smoothed image data can be extracted from the pixel array 211.

For example, MOS transistors can be used as the variable resistance elements VR1 and VR2. However, any resistance element that can change the resistance value can be preferably used without being limited to the MOS transistor. For example, a two-terminal variable resistance element, such as a resistive random access memory (ReRAM), a magnetoresistive random access memory (MRAM), a phase-change memory (PRAM), an ion memory, an amorphous silicon memory, and a polysilicon memory, can be used as at least one of the variable resistance elements VR1 and VR2. In addition, instead of each of the variable resistance elements VR1 and VR2, a variable resistance circuit formed by a plurality of transistors can be provided in a wiring layer 211L. In addition, it is also possible to change the resistance value by switching a plurality of resistance element arrays having different resistance values.

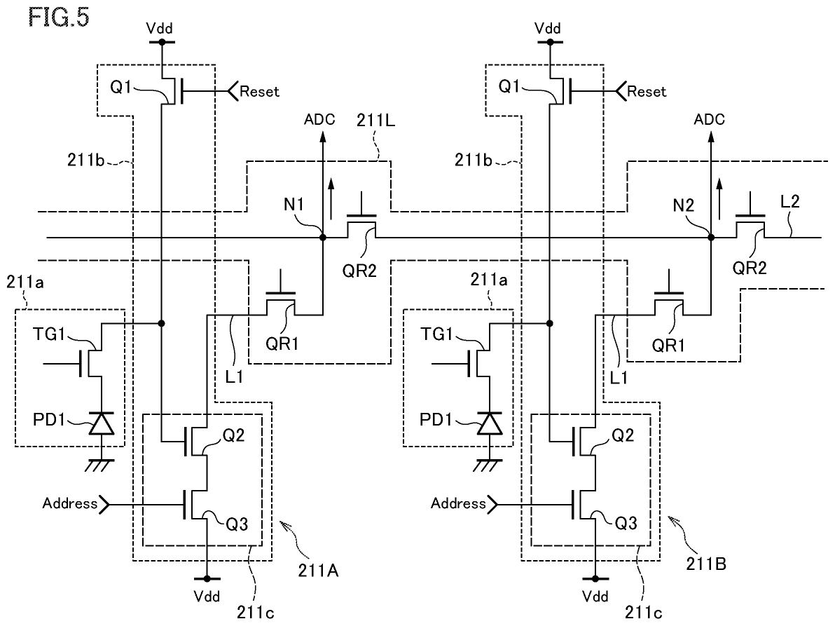

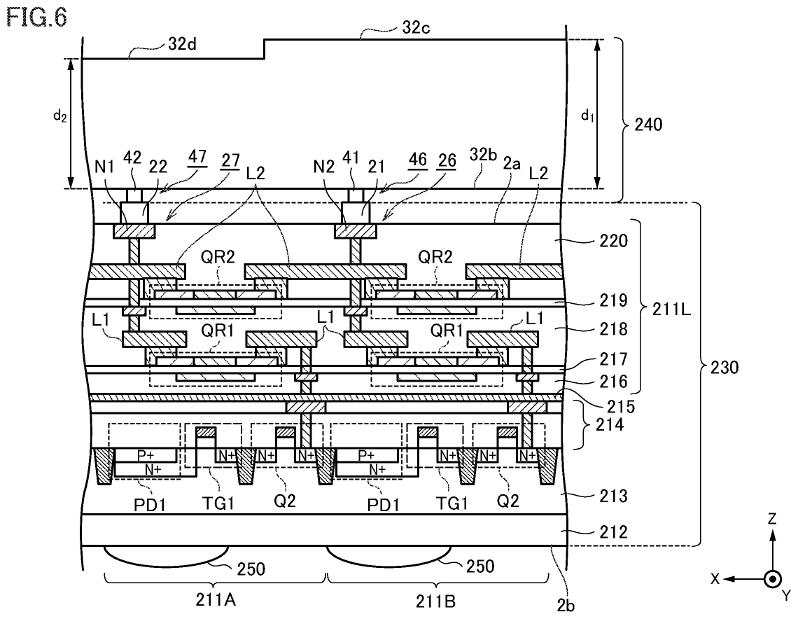

FIG. 5 is a circuit diagram showing a schematic configuration example of an imaging element in which MOS transistors are used as variable resistance elements. As shown in FIG. 5, MOS transistors QR1 and QR2 used as the variable resistance elements VR1 and VR2 are provided in the wiring layer 211L connecting adjacent pixels (for example, the pixel cells 211A and 211B) to each other. FIG. 6 shows an example of the cross-sectional structure of a semiconductor substrate 230 for realizing the circuit configuration shown in FIG. 5. In addition, in FIG. 6, the reset transistor Q1 and the switching transistor Q3 in the amplifier circuit 211c are omitted for convenience of explanation. In addition, although a back emission type device is shown in FIG. 6, a front emission type device may be used without being limited to this.

One pixel cell 211A has a semiconductor substrate 213 on which the photodiodes PD1, the transfer gate TG1, and the amplifier transistor Q2 arranged in a matrix are formed. A color filter 212 is bonded to the back surface of the semiconductor substrate 213. A microlens 250 aligned with the photodiode PD1 is provided on a surface of the color filter 212 opposite to a surface bonded to the semiconductor substrate 213. In addition, light having a specific wavelength according to the color filter 212 can pass from the microlens 250 to the photodiode PD1. For example, a through hole may be formed in the semiconductor substrate 213 between the microlens 250 and the photodiode PD1. In addition, a transparent substrate may be used as the semiconductor substrate 213.

A contact layer 214 is formed on the upper surface of the semiconductor substrate 213. A via for electrically drawing out the source of the amplifier transistor Q2 is formed in the contact layer 214. A pad for facilitating alignment with the upper layer may be formed in the upper portion of the via. In addition, a diffusion prevention film 215 for preventing atomic diffusion between layers is formed on the contact layer 214.

The wiring layer 211L including interlayer insulating films 216 and 218 and a passivation film 220 is formed on the diffusion prevention film 215. Specifically, the interlayer insulating films 216 and 218 are formed on the diffusion prevention film 215. A gate insulating film 217 is formed between the interlayer insulating films 216 and 218. In addition, the MOS transistor QR1 (see FIG. 5) is formed with the gate insulating film 217 located inside the MOS transistor QR1. In addition, in the diffusion prevention film 215, the interlayer insulating film 216, the gate insulating film 217, and the interlayer insulating film 218, a wiring layer and a via for electrically connecting the via electrically drawn out to the upper portion of the contact layer 214 to the drain of the MOS transistor QR1 are formed as a part of the second wiring L1.

The source of the MOS transistor QR1 is electrically drawn out onto the interlayer insulating film 218 through the via formed in the interlayer insulating film 218. A pad (not shown) for facilitating alignment with the upper layer may be formed in the upper portion of the via. A gate insulating film 219 and a passivation film 220 are formed on the interlayer insulating film 218.

The first wiring L2 in FIG. 5 is formed in the passivation film 220. The MOS transistor QR2 are formed with the gate insulating film 219 located inside the MOS transistor QR2. The source of the MOS transistor QR1 electrically drawn out onto the interlayer insulating film 218 is electrically connected to the first wiring L2 through a via formed in the gate insulating film 219 and the passivation film 220 as a part of the second wiring L1. In addition, the node N1 of the first wiring L2 is electrically drawn out to the surface of the passivation film 220 through the via formed in the passivation film 220. Similarly, the node N2 is also electrically drawn out to the surface of the passivation film 220 through the via formed in the passivation film 220. The node N1 and the node N2 are connected to a circuit board 240 through the first bumps 21 and the second bump 22, which will be described later.

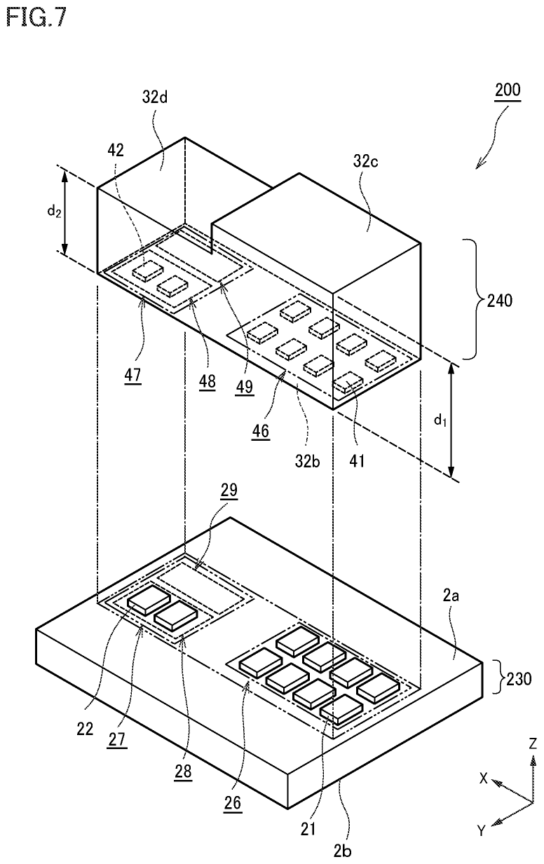

FIG. 7 is a schematic perspective view showing a main part of the electronic component 200 of embodiments. In addition, in FIG. 7, a plurality of first bumps 21 and a plurality of third bumps 41 are shown separated from each other for easy understanding. In addition, in FIG. 7, the second bump 22 and the fourth bump 42 are shown separated from each other for easy understanding.

The circuit board 240 is provided on the semiconductor substrate 230. The circuit board 240 is, for example, a substrate having a peripheral circuit. In addition, the semiconductor substrate 230 is an example of the first substrate. In addition, the circuit board 240 is an example of the second substrate.

A plurality of first bumps 21 are provided in the first region 26 of the first surface 2a of the semiconductor substrate 230. The first bump 21 is connected to the node N2.

In addition, the second bump 22 is provided in the second region 27 of the first surface 2a of the semiconductor substrate 230. The second bump 22 is connected to the node N1.

A plurality of third bumps 41 are provided in the third region 46 of the second surface 32b of the circuit board 240. The plurality of third bumps 41 are connected to the internal wiring (not shown) of the circuit board 240.

A plurality of fourth bumps 42 are provided in the fourth region 47 of the second surface 32b of the circuit board 240. The plurality of fourth bumps 42 are connected to the internal wiring (not shown) of the circuit board 240.

In addition, the semiconductor layer used for the MOS transistors QR1 and QR2 may be an oxide semiconductor such as InGaZnO or ZnO, or may be Poly-Si, amorphous Si, SiGe, and the like. This semiconductor layer may be a stacked film including a plurality of different types of films. As the stacked film, for example, InGaZnO/Al₂O₃/InGaZnO/Al₂O₃ can be used. In addition, various conductive layers, such as a metal wiring and a semiconductor layer doped with impurities, can be used as vias and wiring layers formed in the interlayer insulating films 216 and 218 and the passivation film 220.

As described above, by providing the MOS transistors QR1 and QR2 as the variable resistance elements VR1 and VR2 in the wiring layer 211L formed on the semiconductor substrate 213, image data smoothing processing can be performed at high speed by analog processing without increasing the pixel area.

In addition, the cross-sectional structure shown in FIG. 6 is merely an example. For example, the structures of the MOS transistors QR1 and QR2 formed in the wiring layer 211L are not limited to this. For example, the MOS transistors QR1 and QR2 may have a double gate structure in which gate electrodes are provided above and below the semiconductor layer. In addition, the cross-sectional arrangement of each wiring is not limited to the position shown in FIG. 6. For example, the gate width direction of the MOS transistor QR1 located in the lower layer and the gate width direction of the MOS transistor QR2 located in the upper layer may be perpendicular to each other. In addition, the arrangement of transistors (including the photodiode PD1) formed on the semiconductor substrate 213 is not limited to the arrangement shown in FIG. 6.

According to the electronic component of embodiments as well, it is possible to provide an electronic component in which stress concentration during bonding is suppressed.

While embodiments have been described, embodiments are presented as examples, and it is not intended to limit the scope of the invention. Embodiments can be implemented in various other forms, and various omissions, replacements, and modifications can be made without departing from the scope of the invention. Embodiments or their modifications are included in the scope or gist of the invention, and are included in the scope of the invention described in the claims and their equivalents.

In addition, embodiments described above can be summarized as the following technical proposals.

### (Technical Proposal 1)

An electronic component, including:
a first substrate having a first surface with a first region and a second region, a plurality of first bumps provided in the first region, and zero or one or more second bumps provided in the second region, the number of second bumps being smaller than the number of first bumps; and
a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance, the number of fourth bumps being smaller than the number of third bumps.

### (Technical Proposal 2)

The electronic component according to Technical Proposal 1,
wherein a third area of the third bump within a plane parallel to the second surface is smaller than a first area of the first bump within a plane parallel to the first surface.

### (Technical Proposal 3)

The electronic component according to Technical Proposal 1 or 2,
wherein a fourth area of the fourth bump within a plane parallel to the second surface is smaller than a second area of the second bump within a plane parallel to the first surface.

### (Technical Proposal 4)

The electronic component according to any one of Technical Proposals 1 to 3,
wherein the second distance is 90% or more of the first distance.

### (Technical Proposal 5)

The electronic component according to any one of Technical Proposals 1 to 4,
wherein the second region includes a fifth region having one or more of the second bumps and a sixth region having no second bump, and
the fourth region includes a seventh region having one or more of the fourth bumps and an eighth region having no fourth bump.

### (Technical Proposal 6)

The electronic component according to any one of Technical Proposals 1 to 5,
wherein the first bumps are provided in an array in the first region.

### (Technical Proposal 7)

A method for manufacturing an electronic component, including:

bonding a plurality of first bumps of a first substrate and a plurality of third bumps of a second substrate to each other; and
bonding a second bump of the first substrate and a fourth bump of the second substrate to each other,
wherein the first substrate includes
   a first surface with a first region and a second region;
   the first bumps provided in the first region; and
   zero or one or more second bumps provided in the second region, the number of second bumps being smaller than the number of first bumps, and
the second substrate includes
   a second surface with a third region facing the first surface and the first region and a fourth region facing the second region;
   the third bumps provided in the third region;
   zero or one or more fourth bumps provided in the fourth region, the number of fourth bumps being smaller than the number of third bumps;
   a third surface provided on a side opposite to the third region and having a first distance from the second surface; and
   a fourth surface provided on a side opposite to the fourth region and having a second distance from the second surface shorter than the first distance.

### (Technical Proposal 8)

The method for manufacturing an electronic component according to Technical Proposal 7,
wherein a third area of the third bump within a plane parallel to the second surface is smaller than a first area of the first bump within a plane parallel to the first surface.

### (Technical Proposal 9)

The method for manufacturing an electronic component according to Technical Proposal 7 or 8,
wherein a fourth area of the fourth bump within a plane parallel to the second surface is smaller than a second area of the second bump within a plane parallel to the first surface.

### (Technical Proposal 10)

The method for manufacturing an electronic component according to any one of Technical Proposals 7 to 9,
wherein the second distance is 90% or more of the first distance.

### (Technical Proposal 11)

The method for manufacturing an electronic component according to any one of Technical Proposals 7 to 10,
wherein the second region includes a fifth region having one or more of the second bumps and a sixth region having no second bump, and
the fourth region includes a seventh region having one or more of the fourth bumps and an eighth region having no fourth bump.

### (Technical Proposal 12)

The method for manufacturing an electronic component according to any one of Technical Proposals 7 to 11,
wherein by pressing the third surface and the fourth surface against a sixth surface, the first bumps and the third bumps are bonded to each other, and the second bump and the fourth bump are bonded to each other.

### (Technical Proposal 13)

The method for manufacturing an electronic component according to any one of Technical Proposals 7 to 12,
wherein the first bumps are provided in an array in the first region.

While certain embodiments have been described, these embodiments have been presented by way of example only, and are not intended to limit the scope of the inventions. Indeed, the electronic component and the method for manufacturing the same described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. An electronic component, comprising:
a first substrate having a first surface with a first region and a second region, a plurality of first bumps provided in the first region, and zero or one or more second bumps provided in the second region, the number of second bumps being smaller than the number of first bumps; and
a second substrate having a second surface with a third region facing the first surface and the first region and a fourth region facing the second region, a plurality of third bumps provided in the third region and in contact with the first bumps, zero or one or more fourth bumps provided in the fourth region and in contact with the second bumps, a third surface provided on a side opposite to the third region and having a first distance from the second surface, and a fourth surface provided on a side opposite to the fourth region and having a second distance from the second surface shorter than the first distance, the number of fourth bumps being smaller than the number of third bumps.

2. The electronic component according to claim 1,
wherein a third area of the third bump within a plane parallel to the second surface is smaller than a first area of the first bump within a plane parallel to the first surface.

3. The electronic component according to claim 1,
wherein a fourth area of the fourth bump within a plane parallel to the second surface is smaller than a second area of the second bump within a plane parallel to the first surface.

4. The electronic component according to claim 1,
wherein the second distance is 90% or more of the first distance.

5. The electronic component according to claim 1,
wherein the second region includes a fifth region having one or more of the second bumps and a sixth region having no second bump, and
the fourth region includes a seventh region having one or more of the fourth bumps and an eighth region having no fourth bump.

6. The electronic component according to claim 1,
wherein the first bumps are provided in an array in the first region.

7. A method for manufacturing an electronic component, comprising:
bonding a plurality of first bumps of a first substrate and a plurality of third bumps of a second substrate to each other; and
bonding a second bump of the first substrate and a fourth bump of the second substrate to each other,
wherein the first substrate includes
a first surface with a first region and a second region;
the first bumps provided in the first region; and
zero or one or more second bumps provided in the second region, the number of second bumps being smaller than the number of first bumps, and
the second substrate includes
a second surface with a third region facing the first surface and the first region and a fourth region facing the second region;
the third bumps provided in the third region;
zero or one or more fourth bumps provided in the fourth region, the number of fourth bumps being smaller than the number of third bumps;
a third surface provided on a side opposite to the third region and having a first distance from the second surface; and
a fourth surface provided on a side opposite to the fourth region and having a second distance from the second surface shorter than the first distance.

8. The method for manufacturing an electronic component according to claim 7,
wherein a third area of the third bump within a plane parallel to the second surface is smaller than a first area of the first bump within a plane parallel to the first surface.

9. The method for manufacturing an electronic component according to claim 7,
wherein a fourth area of the fourth bump within a plane parallel to the second surface is smaller than a second area of the second bump within a plane parallel to the first surface.

10. The method for manufacturing an electronic component according to claim 7,
wherein the second distance is 90% or more of the first distance.

11. The method for manufacturing an electronic component according to claim 7,
wherein the second region includes a fifth region having one or more of the second bumps and a sixth region having no second bump, and
the fourth region includes a seventh region having one or more of the fourth bumps and an eighth region having no fourth bump.

12. The method for manufacturing an electronic component according to claim 7,
wherein by pressing the third surface and the fourth surface against a sixth surface, the first bumps and the third bumps are bonded to each other, and the second bump and the fourth bump are bonded to each other.

13. The method for manufacturing an electronic component according to claim 7,
wherein the first bumps are provided in an array in the first region.
